(19) United States
(12) Patent Application Publication
(10) Pub. No.: US 2020/0365426 A1
(43) Pub. Date: Nov. 19, 2020

(54) HIGH-FREQUENCY HEATING DEVICE FOR MOUNTING LED

(71) Applicant: ASTI GLOBAL INC., TAIWAN, Taichung City (TW)

(72) Inventor: CHIEN-SHOU LIAO, New Taipei City (TW)

(21) Appl. No.: 16/662,178

(22) Filed: Oct. 24, 2019

(30) Foreign Application Priority Data
May 13, 2019 (TW) 108116331

(51) Int. Cl. H01L 21/67; H01L 21/673; H01L 33/32; H01L 33/30; H01L 33/06; H05B 6/06; H05B 6/10; B23K 13/02

(52) U.S. Cl. CPC H01L 21/67103; H01L 21/67333; H01L 33/32; B23K 13/02; H01L 33/06; H05B 6/06; H05B 6/101; H01L 33/30

(57) ABSTRACT

A high-frequency heating device for mounting an LED including a carrier substrate and a high-frequency heating module is provided. The carrier substrate is disposed to carry a circuit substrate, and the circuit substrate includes a plurality of conductive pads, a plurality of conductors, and a plurality of LED chips. The conductors are respectively disposed on the conductive pads, and each of the LED chips is disposed on at least two of the plurality of conductors. The high-frequency heating module includes at least one coil assembly disposed above an upper surface of the plurality of LED chips, an upper surface of the carrier substrate, a lower surface of the carrier substrate, or an interior of the carrier substrate. Each of the LED chips is mounted onto the circuit substrate by heating the coil assembly.

### CROSS-REFERENCE TO RELATED PATENT APPLICATION

This application claims the benefit of priority to Taiwan Patent Application No. 108116331 filed on May 13, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a high-frequency heating device, and more particularly to a high-frequency heating device for mounting an LED.

### BACKGROUND OF THE DISCLOSURE

Nowadays, light-emitting diodes (LEDs) are widely used for their excellent light quality and high luminous efficiency. Generally, in order to improve color performance, a conventional display device using a light-emitting diode as a light-emitting element adopts a combination of red, green, and blue light-emitting diode chips to form a full color light-emitting diode display device. The full-color light-emitting diode display device can respectively emit three colors of red, green and blue light through three kinds of red, green and blue light-emitting diode chips, so that a full-color light is formed to display relevant information after mixing of light. However, in the related art, in the process of mounting the LED chip on the circuit substrate, the LED chip is often soldered to the circuit board by soldering.

### SUMMARY OF THE DISCLOSURE

In response to the above-referenced technical inadequacies, the present disclosure provides a high-frequency heating device for mounting an LED.

In one aspect, the present disclosure provides a high-frequency heating device for mounting an LED, including: a carrier substrate and a high-frequency heating module. The carrier substrate is disposed to carry a circuit substrate, and the circuit substrate includes a plurality of conductive pads, a plurality of conductors, and a plurality of LED chips. The conductors are respectively disposed on the conductive pads, and each of the LED chips is disposed on at least two of the plurality of conductors. The high-frequency heating module includes at least one coil assembly disposed above an upper surface of the plurality of LED chips, an upper surface of the carrier substrate, a lower surface of the carrier substrate, or an interior of the carrier substrate. Each of the LED chips is mounted onto the circuit substrate by heating the coil assembly.

In one aspect, the present disclosure provides a high-frequency heating device for mounting an LED, including: a carrier substrate and a high-frequency heating module. The carrier substrate is used to carry a circuit substrate carrying a plurality of conductors and a plurality of LED chips. The high-frequency heating module includes at least one coil assembly disposed above the plurality of LED chips, an upper surface of the carrier substrate, a lower surface of the carrier substrate, or an interior of the carrier substrate. The conductor is heated by the coil assembly to mount the LED chip.

In one aspect, the present disclosure provides a high-frequency heating device for mounting an LED, including: a carrier substrate, a high-frequency heating module, a temperature control module, and a control module. The carrier substrate is disposed to carry a circuit substrate, and the circuit substrate includes a plurality of conductors, and a plurality of LED chips. The high-frequency heating module includes at least one coil assembly disposed above a plurality of the LED chips, an upper surface of the carrier substrate, a lower surface of the carrier substrate, or an interior of the carrier substrate. The temperature control module is adjacent to the carrier substrate for detecting the temperature of the conductor to obtain conductor temperature information. The control module is electrically connected between the temperature control module and the high-frequency heating module. The control module adjusts the power output by the high-frequency heating module according to the conductor temperature information.

Therefore, the high-frequency heating device for mounting the LED provided by the present disclosure has the technical features of “the carrier substrate disposed for carrying a circuit substrate,” “the high-frequency heating module including at least one coil assembly disposed above the plurality of LED chips, the upper surface of the carrier substrate, the lower surface of the carrier substrate, or the interior of the carrier substrate” and “each of the LED chips being mounted onto the circuit substrate by heating the coil assembly” so that the LED chip is mounted on the circuit substrate.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a structural schematic view of a high-frequency heating module of a high-frequency heating device for mounting an LED according to a first embodiment of the present disclosure.

FIG. 2 is an operational schematic diagram of the high-frequency heating device according to the first embodiment of the present disclosure.

FIG. 3 is an operational schematic diagram of the high-frequency heating device according to the first embodiment of the present disclosure.

FIG. 4 is an operational schematic diagram of the high-frequency heating device according to the first embodiment of the present disclosure.

FIG. 5 is an enlarged schematic view of a portion V of FIG. 4.

FIG. 6 is an operational schematic diagram of the high-frequency heating device according to the first embodiment of the present disclosure.

FIG. 7 is a structural schematic view of the high-frequency heating module of the high-frequency heating device according to a second embodiment of the present disclosure.

FIG. 8 is a structural schematic view of the high-frequency heating module of the high-frequency heating device according to a third embodiment of the present disclosure.

FIG. 9 is a structural schematic view of the high-frequency heating module of the high-frequency heating device according to a fourth embodiment of the present disclosure.

FIG. 10 is an operational schematic diagram of a high-frequency heating device according to the second embodiment of the present disclosure.

FIG. 11 is an operational schematic diagram of the high-frequency heating device according to the second embodiment of the present disclosure.

FIG. 12 is a structural schematic view of the high-frequency heating module of the high-frequency heating device according to the third embodiment of the present disclosure.

FIG. 13 is a functional block diagram of the high-frequency heating device according to a third embodiment of the present disclosure.

FIG. 14 is an operational schematic diagram of the high-frequency heating device according to the fourth embodiment of the present disclosure.

FIG. 15 is an operational schematic diagram of the high-frequency heating device according to the fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

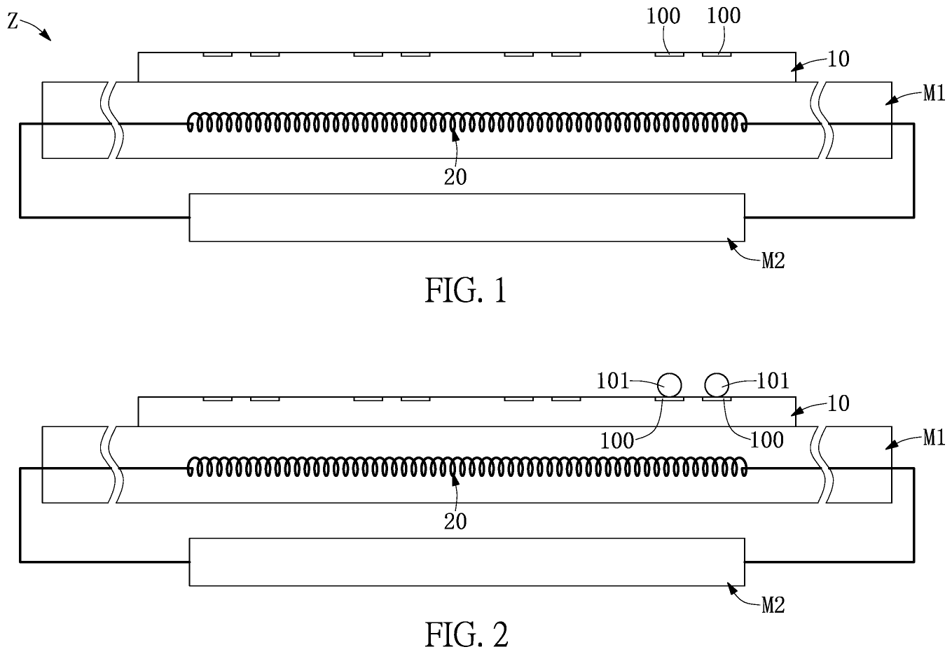

Referring to FIG. 1 to FIG. 9, together with FIG. 13, a first embodiment of the present disclosure provides a high-frequency heating device Z for mounting an LED, including: a carrier substrate M1 and a high-frequency heating module M2.

Firstly, as shown in FIG. 1 and FIG. 2, the carrier substrate M1 carries a circuit substrate 10, and the carrier substrate M1 can be a carrier device with a displacement function, but is not limited thereto. The circuit substrate 10 includes a plurality of conductive pads 100, a plurality of conductors 101, and a plurality of LED chips 102. The conductors 101 are respectively disposed on the conductive pads 100. For example, at least one of the conductors 101 can be disposed on each of the conductive pads 100, and the conductor 101 can be a solder ball or other types of conductive materials, but the present disclosure is not limited thereto. The LED chips 102 are disposed on the circuit substrate 10, and each of the LED chips 102 is disposed on at least two conductors 101.

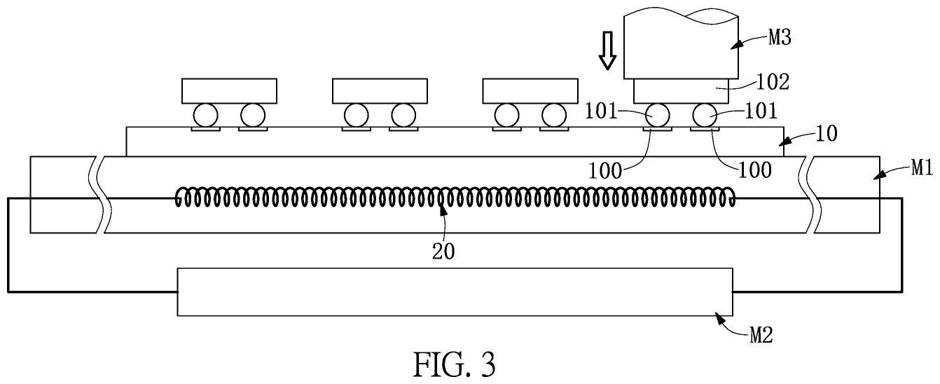

Further, as shown in FIG. 3, the high-frequency heating device Z provided by the present disclosure further includes: a pick and place module M3 adjacent to the carrier substrate M1 for placing each of the LED chips 102 on the corresponding at least two of the conductors 101. For example, the present disclosure can also place a plurality of LED chips 102 on the circuit substrate 10 by the pick and place module M3, and each of the LED chips 102 corresponds to at least two conductors 101. The pick and place module M3 can be a vacuum nozzle or any kind of pick and place machine. However, the present disclosure is not limited thereto.

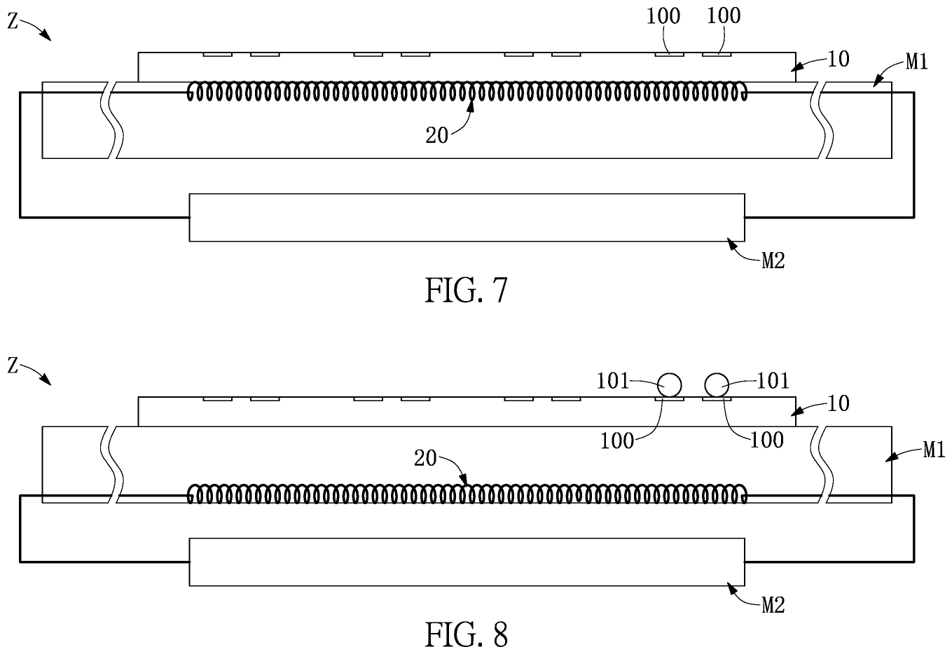

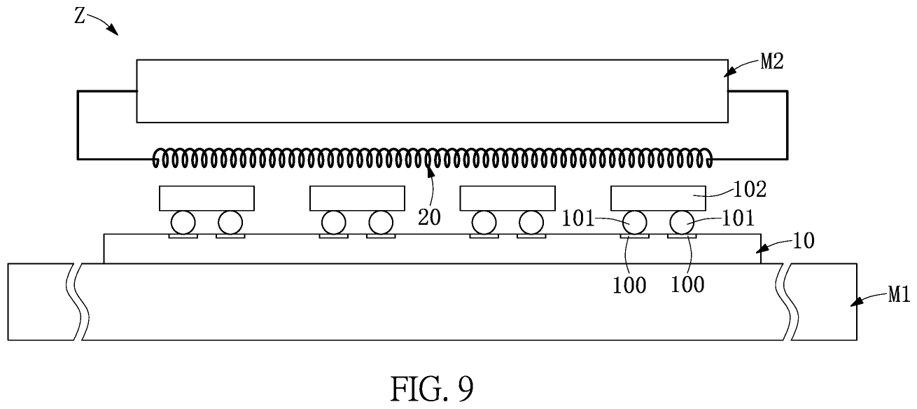

Next, as shown in FIG. 1 to FIG. 4 and FIG. 6 to FIG. 9, the high-frequency heating module M2 may include at least one coil assembly 20. The coil assembly 20 is disposed above the plurality of LED chips 102, on the upper surface of the carrier substrate M1, on the lower surface of the carrier substrate M1, or inside the carrier substrate M1. For example, the coil assembly 20 of the high-frequency heating module M2 may be disposed in the interior of the carrier substrate M1 (as shown in FIG. 1), embedded on the upper surface of the carrier substrate M1 (as shown in FIG. 7), embedded on the lower surface of the carrier substrate M1 (as shown in FIG. 8), or disposed above the LED chip 102 or above the upper surface of the carrier substrate M1 (as shown in FIG. 9). Moreover, the number of the coil assembly 20 may be one or more. In the embodiment, one coil assembly 20 is taken as an example, but not limited thereto.

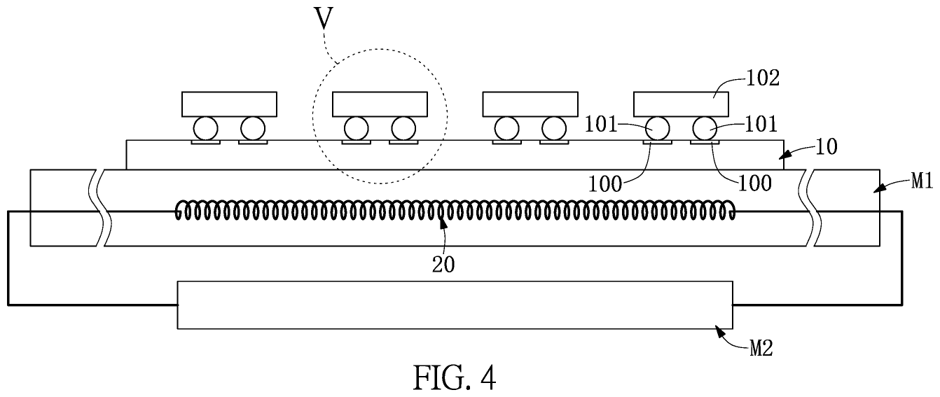

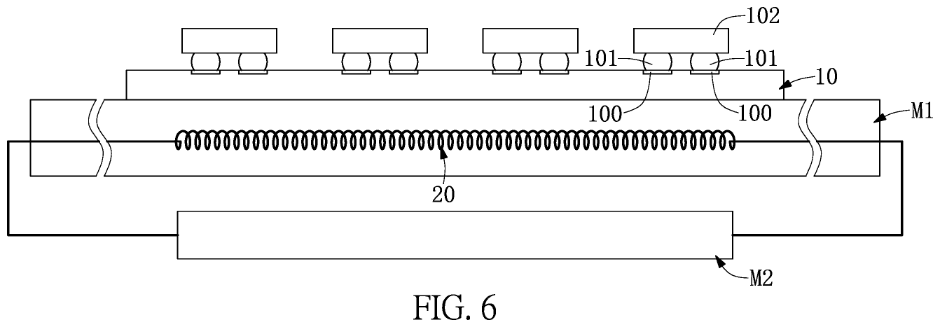

Next, as shown in FIG. 4 and FIG. 6, each of the LED chips 102 is mounted onto the circuit substrate 10 by heating the coil assembly 20. For example, the conductor 101 disposed between the LED chip 102 and the circuit substrate 10 is heated by electromagnetic induction of the coil assembly 20 of the high-frequency heating module M2, so that the conductor 101 is softened to create a connection with the LED chip 102 and the circuit substrate 10.

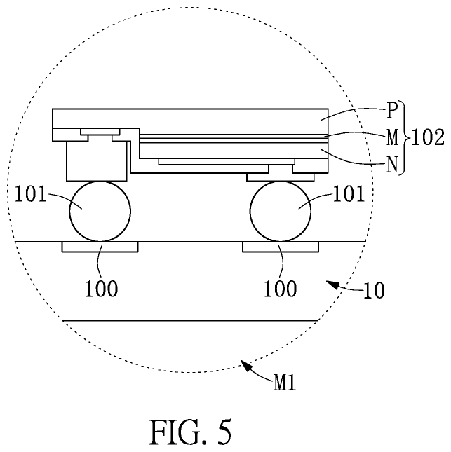

Further, as shown is FIG. 5, the LED chips 102 may be a micro-semiconductor light-emitting element (Micro LED) including an n-type conductive layer N, a light-emitting layer M and a p-type conductive layer P which are arranged in a stacked arrangement. The n-type conductive layer is an n-type gallium nitride material layer or an n-type gallium arsenide material layer, the light-emitting layer is a multi-quantum well structure layer, and the p-type conductive layer is a p-type gallium nitride material layer or a p-type gallium arsenide material layer, but not limited thereto. However, the above-mentioned examples are only one of the possible embodiments and the present disclosure is not limited thereto.

It should be noted that, the high-frequency heating device Z provided by the present disclosure further has effects of double heating and two-stage heating. For example, before or after a heating assembly 20 heats the conductor 101 disposed between the LED chip 102 and the circuit substrate 10, a heating device (not shown, such as a laser heater or other heater) may be further used to heat the conductor 101, so as to shorten the heating time or reduce the output power of the high-frequency heating module M2. However, the above-mentioned examples are only one of the possible embodiments and the present disclosure is not limited thereto.

Further, as shown in FIG. 1 to FIG. 9, the present disclosure further provides the high-frequency heating device Z including the carrier substrate M1 and the high-frequency heating module M2. The carrier substrate M1 is used to carry a circuit substrate 10, and the circuit substrate 10 carries a plurality of conductors 101 and a plurality of LED chips 102. The high-frequency heating module M2 includes at least one coil assembly 20 disposed above the upper surface of the carrier substrate M1, on the upper surface of the carrier substrate M1, on the lower surface of the carrier substrate M1, or inside the carrier substrate M1. The conductor 101 is heated by the assembly 20 to mount the LED chip 102.

### Second Embodiment

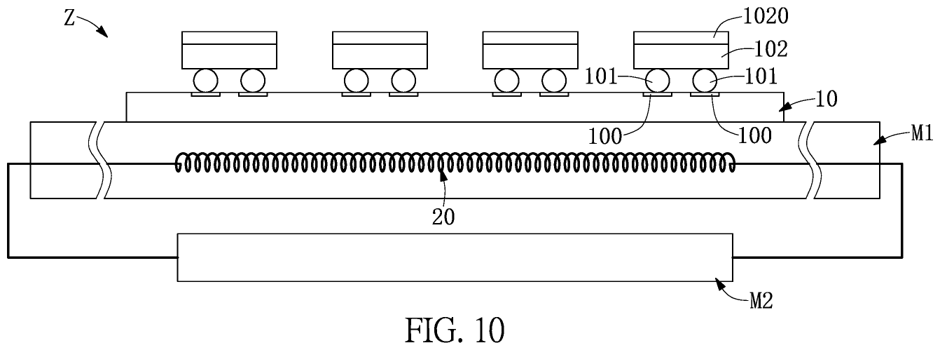

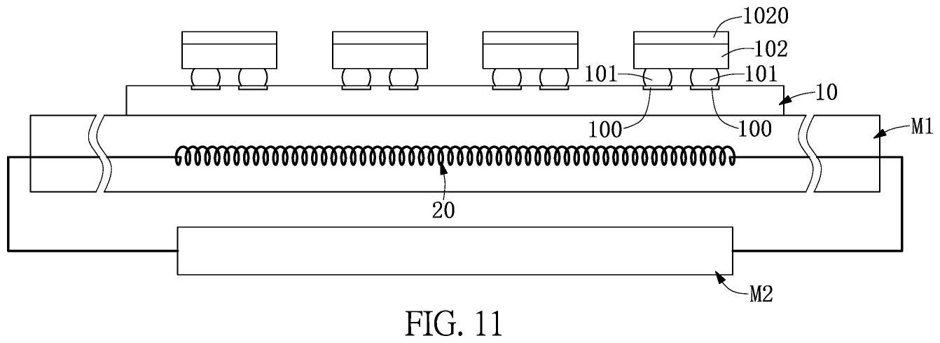

Referring to FIG. 10 to FIG. 11 together with FIG. 1 to FIG. 9, a second embodiment of the present disclosure provides the high-frequency heating device Z that is similar to that described in the first embodiment, and therefore similar steps in the process will not be described again. Further, compared FIG. 4 and FIG. 6 with FIG. 10 and FIG. 11, the difference between the second embodiment and the first embodiment of the present disclosure is that each LED chip 102 of the present embodiment may be a sub-millimeter light-emitting diode (Mini LED) including a base layer 1020, an n-type conductive layer N, a light-emitting layer M, and a p-type conductive layer P disposed in a stacked arrangement. The base layer 1020 is a sapphire material layer, the n-type conductive layer N may be an n-type gallium nitride material layer or an n-type gallium arsenide material layer, the light-emitting layer M is a multi-quantum well structure layer, and the p-type conductive layer P may be a p-type gallium nitride material layer or a p-type gallium arsenide material layer, but is not limited thereto. The base layer 1020 may also be a quartz base layer, a glass base layer, a tantalum base layer, or a base layer of any material.

However, the above-mentioned examples are only one of the possible embodiments and the present disclosure is not limited thereto.

### Third Embodiment

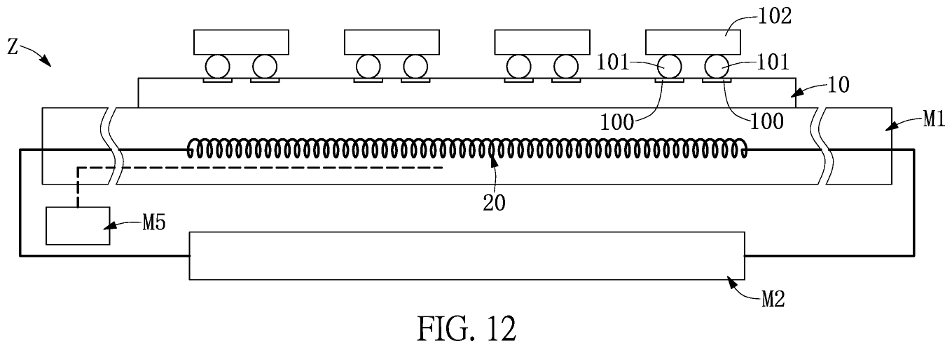

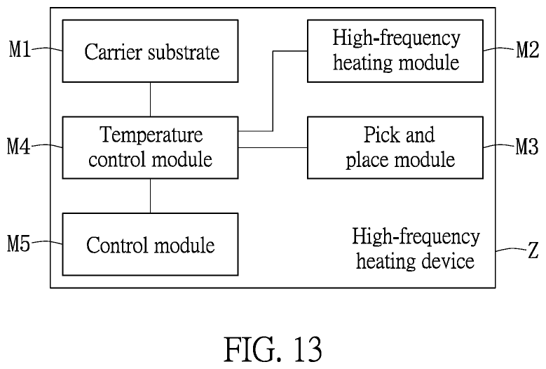

Referring to FIG. 12 to FIG. 13 together with FIG. 1 to FIG. 11, a third embodiment of the present disclosure provides a high-frequency heating device Z for mounting an LED that is similar to that described in the first embodiment, and therefore similar steps in the process will not be described again. Further, the difference between the third embodiment and the first embodiment of the present disclosure is that, the high-frequency heating device Z provided by the present disclosure further includes: a temperature control module M4 and a control module M5. The temperature control module M4 is adjacent to the carrier substrate M1 for detecting the temperature of the conductor 101 to obtain a conductor temperature information. The control module M5 is electrically connected between the temperature control module M4 and a high-frequency heating module M2. The control module M5 adjusts the power output by the high-frequency heating module M2 according to the conductor temperature information.

For example, as shown in FIG. 12 and FIG. 13, the temperature control module M4 can be a temperature sensor or a temperature controller, but the present disclosure is not limited thereto. A sensing end of the temperature control module M4 may be disposed on the carrier substrate M1 and adjacent to the circuit substrate 10, or the sensing end of the temperature control module M4 may be located outside the carrier substrate M1 and adjacent to one or a part of the conductor 101 on the circuit substrate 10. Moreover, the control module M5 is electrically connected to the carrier substrate M1, high-frequency heating module M2, the pick and place module M3, and the temperature control module M4. Therefore, when or after the conductor assembly 20 heats the conductor 101, the temperature of the conductor 101 can be detected by the temperature control module M4 to obtain a conductor temperature information. Then, the control module M5 can determine whether the power output by the high-frequency heating module M2 is sufficient, too low or too high according to the conductor temperature information (for example, by comparing the conductor temperature information with a preset temperature information, but the present disclosure is not limited thereto), and then the power output by the high-frequency heating module M2 is appropriately adjusted. However, the above-mentioned examples are only one of the possible embodiments and the present disclosure is not limited thereto.

It is worth mentioning that, as shown in FIG. 12 to FIG. 13, the present disclosure further provides a high-frequency heating device Z for mounting the LED, including: the carrier substrate M1, the high-frequency heating module M2, the temperature control module M4, and the control module M5. The carrier substrate M1 is used to carry a circuit substrate 10, and the circuit substrate 10 carries the plurality of conductors 101 and a plurality of LED chips 102. The high-frequency heating module M2 includes at least one coil assembly 20 disposed above an upper surface of the carrier substrate M1, on an upper surface of the carrier substrate M1, on a lower surface of the carrier substrate M1, or inside the carrier substrate M1. The temperature control module M4 is adjacent to the circuit substrate 10 for detecting the temperature of the conductor 101 to obtain a conductor temperature information. The control module M5 is electrically connected between the temperature control module M4 and the high-frequency heating module M2. The control module M5 adjusts the power output by the high-frequency heating module M2 according to the conductor temperature information.

### Fourth Embodiment

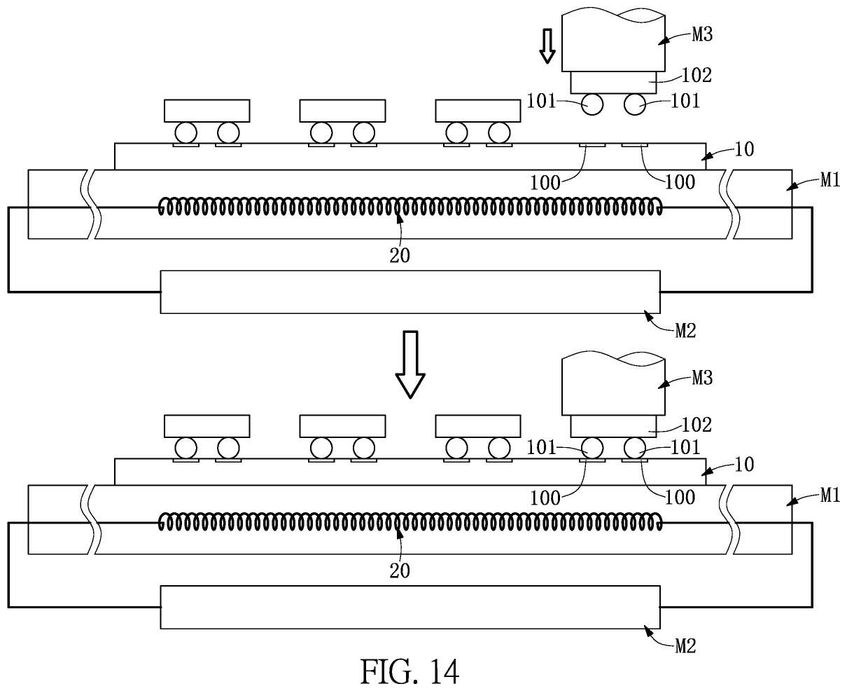

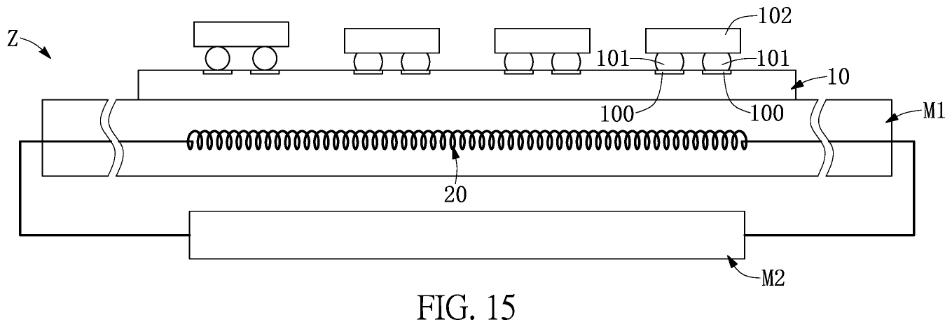

Referring to FIG. 14 to FIG. 15 together with FIG. 1 to FIG. 13, a fourth embodiment of the present disclosure provides a high-frequency heating device Z for mounting an LED that is similar to that described in the first embodiment, and therefore similar steps in the process will not be described again. Further, according to FIG. 1 to FIG. 14, the difference between the fourth embodiment and the first embodiment of the present disclosure is that the high-frequency heating device Z provided by the present disclosure can also have at least two conductors 101 disposed on each LED chip 102.

For example, referring to FIG. 14 and FIG. 15, in the present disclosure, at least two conductors 101 may be disposed on each of the LED chips 102, and the conductor 101 may be a solder ball, or other conductive materials having different shapes or structures, but the present disclosure is not limited thereto. Next, as shown in FIG. 14, the plurality of LED chips 102 are placed on a circuit substrate 10 by the pick and place module M3, and at least two conductors 101 of each of the LED chips 102 corresponds to a plurality of conductive pads 100 of the circuit substrate 10. Then, a high-frequency heating module M2 heats the conductor 101 disposed between the LED chip 102 and the circuit substrate 10 through a coil assembly 20 to soften the conductor 101 and to connect with the circuit substrate 10. Finally, after the conductor 101 is cured, the LED chip 102 is mounted onto the circuit substrate 10 and electrically connected to the circuit substrate 10 through the conductor 101. However, the above-mentioned examples are only one of the possible embodiments and the present disclosure is not limited thereto.

Therefore, the high-frequency heating device Z for mounting the LED provided by the present disclosure has the technical features of “the carrier substrate 10 disposed for carrying the carrier substrate M1,” “the high-frequency heating module M2 including at least one coil assembly 20 disposed above the upper surface of the carrier substrate M1, the upper surface of the carrier substrate M1, the lower surface of the carrier substrate M1, or the inside of the carrier substrate M1” and “each of the LED chips 102 being mounted onto the circuit substrate 10 by heating of the coil assembly 20” so that the LED chip 102 is mounted on the circuit substrate 10.

Furthermore, the high-frequency heating device Z for mounting the LED provided by the present disclosure can adopt the above technical feature to perform a solid crystal forming process of the LED chip 102 by electromagnetic induction using the coil assembly 20 of the high-frequency heating module M2.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A high-frequency heating device for mounting an LED, comprising:
a carrier substrate for carrying a circuit substrate, wherein the circuit substrate includes a plurality of conductive pads, a plurality of conductors, and a plurality of LED chips, the conductors are respectively disposed on the conductive pads, and each of the plurality of LED chips is disposed on at least two of the plurality of conductors; and
a high-frequency heating module including at least one coil assembly disposed above the plurality of LED chips, an upper surface of the carrier substrate, a lower surface of the carrier substrate, or an interior of the carrier substrate;
wherein each of the plurality of LED chips is mounted onto the circuit substrate by heating the coil assembly.

2. The high-frequency heating device according to claim 1, wherein each of the plurality of LED chips includes an n-type conductive layer, a light-emitting layer and a p-type conductive layer which are disposed in a stacked arrangement, the n-type conductive layer is an n-type gallium nitride material layer or an n-type gallium arsenide material layer, the light-emitting layer is a multi-quantum well structure layer, and the p-type conductive layer is a p-type gallium nitride material layer or a p-type gallium arsenide material layer; and wherein the carrier substrate is an opaque substrate.

3. The high-frequency heating device according to claim 1, wherein each of the plurality of LED chips includes a base layer, an n-type conductive layer, a light-emitting layer and a p-type conductive layer which are disposed in a stacked arrangement, the base layer is a sapphire base layer, the n-type conductive layer is an n-type gallium nitride material layer or an n-type gallium arsenide material layer, the light-emitting layer is a multi-quantum well structure layer, and the p-type conductive layer is a p-type gallium nitride material layer or a p-type gallium arsenide material layer; and wherein the carrier substrate is an opaque substrate.

4. The high-frequency heating device according to claim 1, further comprising: a pick and place module adjacent to the carrier substrate for placing each of the plurality of LED chips on at least two of the plurality of conductors; wherein each of the plurality of conductors is cured by heating of the at least one coil assembly such that each of the plurality of LED chips is mounted onto the circuit substrate.

5. The high-frequency heating device according to claim 1, further comprising:
a temperature control module adjacent to the carrier substrate for detecting the temperature of the plurality of conductors so as to obtain conductor temperature information; and
a control module electrically connected between the temperature control module and the high-frequency heating module;
wherein the control module adjusts the power output by the high-frequency heating module according to the conductor temperature information.

6. A high-frequency heating device for mounting an LED, comprising:
a carrier substrate for carrying a circuit substrate, the circuit substrate carrying a plurality of conductors and a plurality of LED chips; and
a high-frequency heating module including at least one coil assembly disposed above an upper surface of the carrier substrate, an upper surface of the carrier substrate, a lower surface of the carrier substrate, or an interior of the carrier substrate; wherein the conductor is heated by the at least one coil assembly to mount the LED chip.

7. The high-frequency heating device according to claim 6, wherein each of the LED chips includes an n-type conductive layer, a light-emitting layer and a p-type conductive layer which are disposed in a stacked arrangement, the n-type conductive layer is an n-type gallium nitride material layer or an n-type gallium arsenide material layer, the light-emitting layer is a multi-quantum well structure layer, and the p-type conductive layer is a p-type gallium nitride material layer or a p-type gallium arsenide material layer.

8. The high-frequency heating device according to claim 6, wherein each of the LED chips includes a base layer, an n-type conductive layer, a light-emitting layer and a p-type conductive layer which are disposed in a stacked arrangement, the base layer is a sapphire base layer, the n-type conductive layer is an n-type gallium nitride material layer or an n-type gallium arsenide material layer, the light-emitting layer is a multi-quantum well structure layer, and the p-type conductive layer is a p-type gallium nitride material layer or a p-type gallium arsenide material layer.

9. The high-frequency heating device according to claim 6, further comprising:
a temperature control module adjacent to the carrier substrate for detecting the temperature of the conductor so as to obtain a conductor temperature information; and
a control module electrically connected between the temperature control module and the high-frequency heating module;
wherein the control module adjusts the power output by the high-frequency heating module according to the conductor temperature information.

10. A high-frequency heating device for mounting an LED, comprising:
a carrier substrate for carrying a circuit substrate, wherein the circuit substrate includes a plurality of conductors and a plurality of LED chips;
a high-frequency heating module including at least one coil assembly disposed above an upper surface of the carrier substrate, an upper surface of the carrier substrate, a lower surface of the carrier substrate, or an interior of the carrier substrate;
a temperature control module adjacent to the carrier substrate for detecting the temperature of the conductor so as to obtain a conductor temperature information; and
a control module electrically connected between the temperature control module and the high-frequency heating module;
wherein the control module adjusts the power output by the high-frequency heating module according to the conductor temperature information.
